(19) United States
(12) Patent Application Publication
(10) Pub. No.: US 2012/0146737 A1
(43) Pub. Date: Jun. 14, 2012

(54) MULTIPLE-OUTPUT CLOCK SOURCE SIGNAL GENERATOR

(75) Inventors: HSIANG-SHENG WEN, Pingzhen City (TW); CHING-FENG HSIEH, Taipei City (TW)

(73) Assignee: ASKEY COMPUTER CORP., TAIPEI (TW)

(21) Appl. No.: 13/010,119

(22) Filed: Jan. 20, 2011

(30) Foreign Application Priority Data
Dec. 14, 2010 (TW) 099143762

(51) Int. Cl. H03B 5/32

(52) U.S. Cl. 331/158

(57) ABSTRACT

A multiple-output clock source signal generator for use with a fiber-optic communication apparatus for multi-dwelling units (MDU) includes a piezoelectric crystal, an input capacitor, an output capacitor, and a buffer unit having output ends. The piezoelectric crystal, the input capacitor, and the output capacitor are connected to the buffer unit so as to form a feedback circuit whereby the piezoelectric crystal oscillates and generates clock source signals to be output from the output ends, respectively. The multiple-output clock source signal generator is advantageously characterized by low costs and multiple output.

### CROSS-REFERENCE TO RELATED APPLICATION

This non-provisional application claims priority under 35 U.S.C. §119(a) on Patent Application No(s). 099143762 filed in Taiwan, R.O.C. on Dec. 14, 2010, the entire contents of which are hereby incorporated by reference.

### FIELD OF THE TECHNOLOGY

The present invention relates to multiple-output clock source signal generators, and more particularly, to a multiple-output clock source signal generator for use with a fiber-optic communication apparatus for multi-dwelling units (MDU).

### BACKGROUND

According to related prior art, a circuit inside a communication apparatus has to be provided with a basic clock source signal for enabling the communication apparatus to operate. For example, a basic clock source signal is required for the operation of a phase-locked loop (PLL). In general, the clock source signal can be generated by a quartz oscillator, provided that the quartz oscillator is capable of generating precise clock source signals. However, the clock source signal generated by the quartz oscillator can only drive a single circuit, and, as a result, fails to meet the need of providing a clock source signal for a plurality of circuits in the communication apparatus concurrently.

In attempt to solve the aforesaid problem, the prior art teaches generating a plurality of clock source signals by a plurality of said quartz oscillators, respectively. Alternatively, the prior art teaches augmenting the strength of a clock source signal by means of an amplifying element configured to increase signal gain and then supplying the amplified clock source signal to a plurality of circuits. Although the aforesaid conventional solutions effectuate the supply of the clock source signal to a plurality of circuits, the aforesaid conventional solutions incur additional communication apparatus manufacturing costs due to the high unit price of the quartz oscillators.

Accordingly, to overcome the aforesaid drawback of the prior art, it is imperative to provide a solution effective in outputting a plurality of clock source signals and cutting costs.

### SUMMARY

It is a primary objective of the present invention to provide a multiple-output clock source signal generator for providing a multiple-output clock source by means of a low-cost piezoelectric crystal.

In order to achieve the above and other objectives, the present invention provides a multiple-output clock source signal generator for use with a fiber-optic communication apparatus for multi-dwelling units (MDU). The multiple-output clock source signal generator comprises a piezoelectric crystal, an input capacitor, an output capacitor, and a buffer unit. The piezoelectric crystal has a first connecting end and a second connecting end. The input capacitor has an end connected to the first connecting end of the piezoelectric crystal and another end grounded. The output capacitor has an end connected to the second connecting end of the piezoelectric crystal and another end grounded. The buffer unit has a plurality of output ends, a third connecting end, and a fourth connecting end. A feedback circuit is formed by connecting the third connecting end to the first connecting end of the piezoelectric crystal and the input capacitor and connecting the fourth connecting end to the second connecting end of the piezoelectric crystal and the output capacitor. The feedback circuit is configured to enable the piezoelectric crystal to oscillate and generate a plurality of clock source signals such that the clock source signals are sent out from the output ends of the buffer unit, respectively.

Compared with the prior art, the present invention provides a multiple-output clock source signal generator configured for use with a fiber-optic communication apparatus and configured to supply the fiber-optic communication apparatus with multiple-output clock source signals in the form of a plurality of clock source signals generated by a single piezoelectric crystal, wherein the multiple-output clock source signal generator comprises a low-cost piezoelectric crystal connected to capacitors and a buffer unit. Unlike the prior art which teaches using a plurality of high-cost quartz oscillators to generate a plurality of clock source signals, the present invention discloses a multiple-output clock source signal generator that is effective in cutting costs. Also, the present invention has a further advantage, that is, generating stable and precise clock source signals by adjusting the capacitance levels of all the capacitors connected to the piezoelectric crystal.

### BRIEF DESCRIPTION OF THE DRAWINGS

To enable persons skilled in the art to fully understand the objectives, features, and advantages of the present invention, the present invention is hereunder illustrated with specific embodiments in conjunction with the accompanying drawings, in which:

FIG. 1 is a schematic view of a multiple-output clock source signal generator according to an embodiment of the present invention.

### DETAILED DESCRIPTION

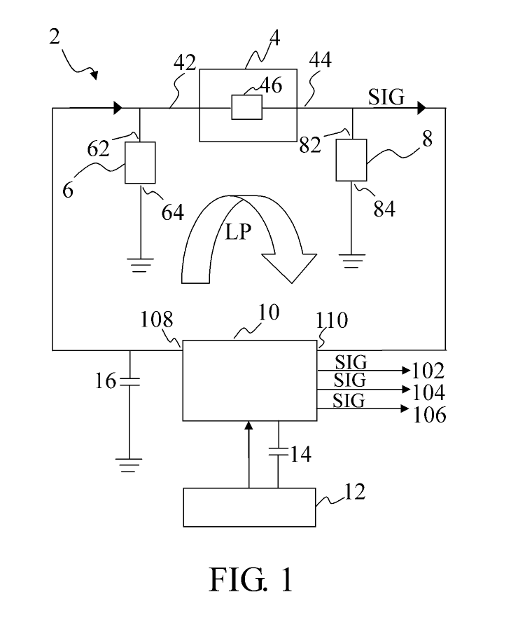

Referring to FIG. 1, there is shown a schematic view of a multiple-output clock source signal generator 2 according to an embodiment of the present invention. As shown in FIG. 1, the multiple-output clock source signal generator 2 is configured for use with a fiber-optic communication apparatus for multi-dwelling units (MDU). The multiple-output clock source signal generator 2 comprises a piezoelectric crystal 4, an input capacitor 6, an output capacitor 8, and a buffer unit 10.

The piezoelectric crystal 4 has a first connecting end 42 and a second connecting end 44. One end of the first connecting end 42 and one end of the second connecting end 44 are connected to a piezoelectric material 46 disposed inside the piezoelectric crystal 4. Due to its piezoelectric effect, the piezoelectric crystal 4 is capable of stress field and electric field coupling. For example, the piezoelectric material 46 is barium titanate (BT), lead zirconate titanate (PZT), monocrystalline quartz, tourmaline, Rochelle salts, tantalate, niobate, or zinc oxide (ZnO). In an embodiment, the piezoelectric crystal 4 comes in the form of a quartz crystal for generating by oscillation thereof a clock source signal at a frequency of 35.328 MHz, such that the clock source signal can be used as a basic clock source for the fiber-optic communication apparatus.

Likewise, the input capacitor 6 has two second connecting ends 62, 64. The second connecting end 62 of the input capacitor 6 is connected to the first connecting end 42 of the piezoelectric crystal 4. The second connecting end 64 of the input capacitor 6 is grounded. The input capacitor 6 is of a specific capacitance level.

Likewise, the output capacitor 8 has two second connecting ends 82, 84. The second connecting end 82 of the output capacitor 8 is connected to the second connecting end 44 of the piezoelectric crystal 4. The second connecting end 84 of the output capacitor 8 is grounded. The output capacitor 8 is of a specific capacitance level.

The buffer unit 10 has a plurality of output ends 102, 104, 106, a third connecting end 108, and a fourth connecting end 110. A feedback circuit LP is formed by connecting the third connecting end 108 to the first connecting end 42 of the piezoelectric crystal 4 and the second connecting end 62 of the input capacitor 6 and connecting the fourth connecting end 110 to the second connecting end 44 of the piezoelectric crystal 4 and the second connecting end 82 of the output capacitor 8. The feedback circuit LP enables the piezoelectric crystal 4 to oscillate and generate a plurality of clock source signals SIG, such that the clock source signals SIG are sent out from the output ends 102, 104, 106 of the buffer unit 10, respectively. The buffer unit 10 is an integrated circuit (IC), such as μA741 operational amplifier.

Furthermore, the feedback circuit LP enables the piezoelectric crystal 4 to bring about an inverse piezoelectric effect. The inverse piezoelectric effect results in the elongation of the piezoelectric material 46 in the direction of an applied electric (or voltage). The elongation of the piezoelectric material 46 in the direction of the applied electric (or voltage) field occurs, because the applied electric (or voltage) field propagates to the surface of the piezoelectric material 46 through the connecting ends to thereby cause a change in an electric dipole moment inside the piezoelectric material 46, and in consequence the piezoelectric material 46 elongates so as to go against the change in the electric dipole moment.

The multiple-output clock source signal generator 2 further comprises a power supply unit 12. The power supply unit 12 is connected to the buffer unit 10. The power supply unit 12 is configured to drive the buffer unit 10, such that the buffer unit 10 drives the feedback circuit LP to operate.

The multiple-output clock source signal generator 2 further comprises a load capacitor 14. The load capacitor is connected to the buffer unit 10 and the power supply unit 12. The multiple-output clock source signal generator 2 further comprises a stray capacitor 16. The stray capacitor 16 is an electronic component. Alternatively, the stray capacitor 16 is not an electronic component; instead, the stray capacitor 16 comes in the form of stray capacitance, and the stray capacitance level is inherently set during a circuit fabrication process, as indicated by an equivalent circuit shown in FIG. 1. Hence, the capacitance levels of the load capacitor 14, the input capacitor 6, the output capacitor 8, and the stray capacitor 16 are configured to be correlative and interactive, so as to stabilize the clock source signals SIG; in other words, the multiple-output clock source signal generator 2 can be varied by adjusting the capacitance levels of the load capacitor 14, the input capacitor 6, the output capacitor 8, and the stray capacitor 16, respectively. Also, the buffer unit 10 and the load capacitor 14 are series-connected or parallel-connected to the piezoelectric crystal 4.

Compared with the prior art, the present invention provides a multiple-output clock source signal generator configured for use with a fiber-optic communication apparatus and configured to supply the fiber-optic communication apparatus with multiple-output clock source signals in the form of a plurality of clock source signals generated by a single piezoelectric crystal, wherein the multiple-output clock source signal generator comprises a low-cost piezoelectric crystal connected to capacitors and a buffer unit. Unlike the prior art which teaches using a plurality of high-cost quartz oscillators to generate a plurality of clock source signals, the present invention discloses a multiple-output clock source signal generator that is effective in cutting costs. Also, the present invention has a further advantage, that is, generating stable and precise clock source signals by adjusting the capacitance levels of all the capacitors connected to the piezoelectric crystal.

The foregoing embodiments are provided to illustrate and disclose the technical features of the present invention so as to enable persons skilled in the art to understand the disclosure of the present invention and implement the present invention accordingly, and are not intended to be restrictive of the scope of the present invention. Hence, all equivalent modifications and replacements made to the foregoing embodiments without departing from the spirit embodied in the disclosure of the present invention should fall within the scope of the present invention as set forth in the appended claims. Accordingly, the legal protection for the present invention should be defined by the appended claims.

What is claimed is:

1. A multiple-output clock source signal generator for use with a fiber-optic communication apparatus for multi-dwelling units (MDU), comprising:
a piezoelectric crystal having a first connecting end and a second connecting end;
an input capacitor having an end connected to the first connecting end of the piezoelectric crystal and another end grounded;
an output capacitor having an end connected to the second connecting end of the piezoelectric crystal and another end grounded; and
a buffer unit having a plurality of output ends, a third connecting end, and a fourth connecting end, wherein a feedback circuit is formed by connecting the third connecting end to the first connecting end of the piezoelectric crystal and the input capacitor and connecting the fourth connecting end to the second connecting end of the piezoelectric crystal and the output capacitor and configured to enable the piezoelectric crystal to oscillate and generate a plurality of clock source signals such that the clock source signals are sent out from the output ends of the buffer unit, respectively.

2. The multiple-output clock source signal generator of claim 1, further comprising a power supply unit connected to the buffer unit and configured to drive the buffer unit, thereby allowing the buffer unit to drive the feedback circuit to operate.

3. The multiple-output clock source signal generator of claim 2, further comprising a load capacitor and a stray capacitor, the load capacitor being connected to the buffer unit and the power supply unit, wherein capacitance levels of the load capacitor, the input capacitor, the output capacitor, and the stray capacitor are configured to be correlative and interactive, so as to stabilize the clock source signals.

4. The multiple-output clock source signal generator of claim 3, wherein the buffer unit and the load capacitor are series-connected or parallel-connected to the piezoelectric crystal.

5. The multiple-output clock source signal generator of claim 1, wherein the piezoelectric crystal comprises a piezoelectric material, and the piezoelectric material is connected to the first connecting end and the second connecting end.

6. The multiple-output clock source signal generator of claim 5, wherein the piezoelectric material is one of barium titanate (BT), lead zirconate titanate (PZT), monocrystalline quartz, tourmaline, Rochelle salt, tantalate, niobate, and zinc oxide (ZnO).

7. The multiple-output clock source signal generator of claim 1, wherein the piezoelectric crystal oscillates and generates the clock source signals at a frequency of 35.328 MHz.
